(19) United States
(12) Patent Application Publication
(10) Pub. No.: US 2010/0071194 A1
(43) Pub. Date: Mar. 25, 2010

(54) Ultrasonic system and method for affixing a screen sub-assembly to a plate

(76) Inventors: Robert G. Derrick, Orchard Park, NY (US); Ronald J. Schiller, Lancaster, NY (US)

Correspondence Address: Adams and Reese LLP, 1221 McKinney Street, Suite 4400, Houston, TX, 77010, US

(21) Appl. No.: 12/231,961

(22) Filed: Sep. 8, 2008

Related U.S. Application Data
(60) Provisional application No. 60/970,774, filed on Sep. 7, 2007.

(51) Int. Cl. H05K 13/00

(52) U.S. Cl. 29/592.1

(57) ABSTRACT

In one embodiment of the present invention, a method of affixing a screen sub-assembly to a substrate includes the steps of depositing a thermoplastic material on a surface of the substrate and placing the screen sub-assembly on top of the substrate. The screen sub-assembly includes a screen element and a thermoplastic material. The method also includes the steps of placing the screen sub-assembly and the substrate on a movable surface and driving the movable surface across a base support surface so as to position the screen sub-assembly and the substrate below an ultrasonic welding device. The ultrasonic welding device is actuated to emit ultrasonic energy that results in the screen sub-assembly being affixed to the substrate. The substrate can be formed of a perforated metal plate and a coating of thermoplastic powder.

### CROSS-REFERENCE TO RELATED APPLICATION

The present application claims the benefit of U.S. patent application Ser. No. 60/970,774, filed Sep. 7, 2007, which is hereby incorporated by reference in its entirety.

### TECHNICAL FIELD

The present invention relates to a system and method for attaching one article to another article and more particularly relates to a system and method for affixing a screen sub-assembly to a substrate using ultrasonic technology.

### BACKGROUND

Screen sub-assemblies are affixed to plates to form assemblies that can be used for various screening applications.

### SUMMARY

In one embodiment of the present invention, a method of affixing a screen sub-assembly to a substrate includes the steps of depositing a thermoplastic material on a surface of the substrate and placing the screen sub-assembly on top of the substrate. The screen sub-assembly includes a screen element and a thermoplastic material. The substrate can be formed of a perforated metal plate and a coating of thermoplastic powder. The method also includes the steps of placing the screen sub-assembly and the substrate on a movable surface and driving the movable surface across a base support surface so as to position the screen sub-assembly and the substrate below an ultrasonic welding device. The ultrasonic welding device is actuated to emit ultrasonic energy that results in the screen sub-assembly being affixed to the substrate.

### BRIEF DESCRIPTION OF THE DRAWINGS

Aspects of the present invention will now be described by way of exemplary embodiments with reference to the following drawing, in which:

FIG. 1 is a side elevation view of a system for ultrasonically affixing a screen sub-assembly to a substrate, such as a metal plate, according to an exemplary embodiment of the present invention;

FIG. 2 is a side elevation view showing a woven wire sub-assembly and a thermoplastic coated substrate according to an exemplary embodiment of the present invention; and

FIG. 3 is a side elevation view of components of a substrate, according to an exemplary embodiment of the present invention.

FIG. 4 is an exploded side elevation view of components of a woven wire sub-assembly, according to an exemplary embodiment of the present invention.

### DETAILED DESCRIPTION

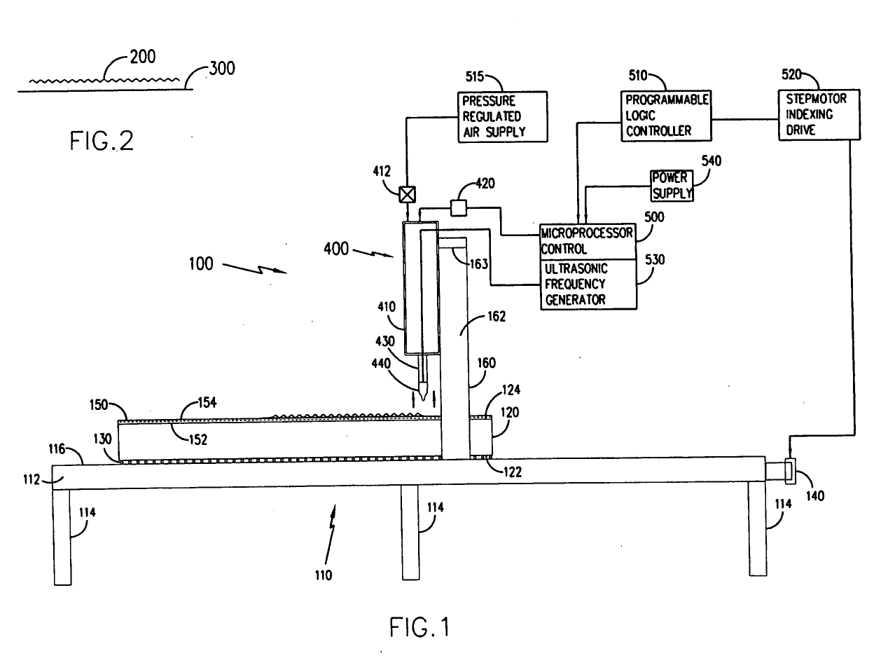

According to one embodiment of the present invention, a system 100 for affixing a screen sub-assembly 200 to a substrate 300 is shown in FIGS. 1-4. The system 100 includes a support structure 110 such as a table. The table 110 includes a base (support surface) 112 and a plurality of legs 114 that extend from and support the base 112 in an elevated manner. Table 110 may be structurally configured in a sturdy manner so as to reduce or prevent secondary vibrations from occurring when ultrasonic welding, as discussed below, is performed. The base 112 include a planar top surface 116 on which an item can be placed and supported. The system 100 also includes a movable support structure 120 that is supported on and movable relative to and across the top surface 116 of the base 112. For example, the movable support structure 120 can be in the form of a movable substrate, block or table that is complementary to and can move across the top surface 116. In the illustrated embodiment, the movable support structure 120 is in the form of a movable table or block that includes a planar bottom surface 122 and an opposite planar top surface 124.

In order to facilitate the movement of the support structure 120 relative to the top surface 116 of the base 110, bearings 130 or the like can be provided between the bottom surface 122 of the movable support structure 120 and the top surface 116 of the base 110. The use of bearings 130 allows the support structure (table) 120 to slide over the top surface 116 of the base 110.

The system 100 also includes a driver 140 for controllably driving (moving) the support structure 120 across the base 110. The driver 140 may be designed to precisely position the support structure 120 relative to the top surface 116 of the base 110 or other reference structure. Any number of different drivers can be used so long as they can position the support structure 120 relative to the base 110 with precision. For example, the driver 140 can be a stepper motor. The stepper motor 140 may be a brushless, synchronous electric motor that can divide a full rotation into a large number of steps. When commutated electronically, the motor's position can be controlled precisely, without any feedback mechanism. The stepper motor 140 thus allows the position of the support structure 120 to be controlled with a high degree of precision and allows the support structure 120 to be controllably advanced along the top surface 116 of the base 110 to a desired position (e.g., a coordinate location).

The support structure 120 can also include a covering 150 that is disposed across the top surface 124 of the movable support structure 120. For example, the covering 150 can be a planar sheet (e.g., rubber sheet). The rubber sheet 150 is coupled to the top surface 124 of the support structure 120. The sheet 150 has a planar bottom surface 152 and an opposing planar top surface 154. For example, the rubber sheet 150 may be affixed to the top surface 124 by bonding (e.g., adhesives), mechanical attachment, etc. The bottom surface 152 is thus attached to the top surface 124 of the support structure 120. Rubber sheet 150 is advantageous in that it reduces vibrations when ultrasonic welding procedures, as discussed herein, are performed. Additionally, rubber sheet 150 greatly reduces noise during ultrasonic welding.

The system 100 also includes a bridge 160 that is positioned above and coupled to the base 110. The bridge 160 can have a U-shape in that it includes a pair of side supports (legs) 162 and a cross beam 163 that extends between the side supports 162. The side supports 162 are coupled to the base 110 and may be located at or near the sides (edges) of the base 110. The cross beam thus extends across the base 110 between the sides thereof and may be oriented relatively perpendicular to the side supports 162. The side supports 162 are positioned so that the movable support structure 120 can travel between the side supports 162 beneath the cross beam. The movable support structure 120 can thus pass entirely underneath and clear the bridge 160. The side supports 162 may be perpendicularly oriented with respect to the base 110 and the cross beam is located parallel to the top surface 124 of the support structure 120.

The system 100 also includes a device 400 for affixing the screen sub-assembly 200 to the substrate 300. The device 400 is configured to couple the screen sub-assembly 200 to the substrate 300 by emitting energy. For example, the device 400 can be configured to use ultrasonic energy to bond the screen sub-assembly 200 to the substrate 300. The device 400 can be an ultrasonic welding head assembly that includes a piston 410 to drive the device 400 from one operating position to another operating position. Device 400 may include multiple pistons coupled with ultrasonic welding heads configured to affix screen sub-assembly 200 to substrate 300 at multiple points. In one embodiment, the piston 410 is in the form of a pneumatic piston that uses a difference in pressure to move the piston 410. The pneumatic piston 410 has a valve 412 that controls airflow to the piston 410 which moves the piston 410 within a cylinder or the like and is contained at an air source 515.

As shown in FIG. 1, the device 400 is vertically oriented relative to the base 110 and the support structure 120 and thus, the piston 410 is driven vertically in an up and down motion resulting in the end of the piston 410 being positioned further from or closer to the support structure 120.

The device 400 can also include a differential pressure transducer 420 to report the differential pressure to a microprocessor (controller) 500 that is in communication with the operating parts of the system 100. The transducer 420 is thus used to control the positioning of the piston 410. The device 400 can include an ultrasonic transducer and booster 430 that is attached to the piston 410. For example, the ultrasonic transducer and booster 430 is located at a distal tip of the piston 410.

The ultrasonic transducer 430 is a device that converts energy into ultrasound, or sound waves above the normal range of human hearing. The ultrasonic transducer can be in the form of a piezoelectric transducer that converts electrical energy into sound. Piezoelectric crystals have the property of changing size when a voltage is applied, thus applying an alternating voltage (AC) across them that causes the crystals to oscillate at very high frequencies, thus producing very high frequency sound waves.

The device 400 also can include a shaped metal horn 440 that is attached to the booster 430 to direct the ultrasonic motion. In other words, the metal horn 440 focuses the ultrasonic motion toward a target, in this case, an object on the movable support structure 120.

The system 100 also includes an assembly of electronic control components that can be configured to power and position the movable support structure 120 and the ultrasonic welding head 430. For example, a programmable logic controller 510 that is in communication with the working components, including the microprocessor 500 and a stepper motor indexing drive controller 520 that is used for controlling the stepper motor 140 with a high degree of precision that is translated into moving the movable support structure 120 with a high degree of precision. In addition, the system 100 includes an ultrasonic frequency generator 530 that is in communication with other working components, such as the device 400 and the microprocessor 500. A power supply 540 is also provided for providing a power source to the system 100. The power supply 540 is thus operably connected to other components, including the microprocessor 500.

The system 100 thus is configured to move an object via the movable support structure 120 across the base 110 to a position where the object is positioned proximate the device 400 so that upon actuation thereof, ultrasonic energy is generated and directed toward the object.

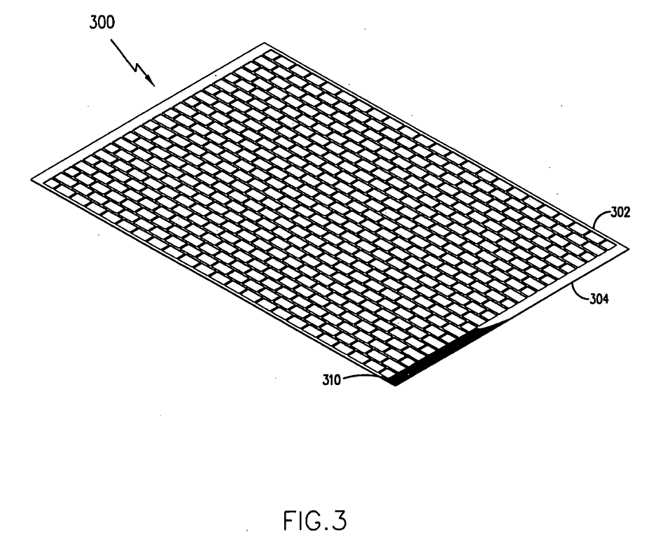

In one embodiment of the present invention, the system 100 is used to affix the screen sub-assembly 200 to the substrate 300. The substrate 300 can be any number of different substrates (e.g., a cast metal frame or welded frame or other frame structure), including a metal plate that has a planar top surface 302 and an opposite planar bottom surface 304. In one embodiment, as shown in FIG. 3, the substrate 300 is a perforated metal plate that is further prepared by applying a coating (layer) 310 of a thermoplastic material on the planar top surface 302 so as to coat or form a layer thereon. The thermoplastic material may be initially in the form of a thermoplastic powder but may also be in other forms. The metal plate 300 is heated to a temperature that causes the thermoplastic powder 310 to melt on contact with the metal plate 300. Thus, the application of the thermoplastic powder 310 to the heated plate 300 results in the powder melting to form the thermoplastic layer or coating 310. By adjusting the temperature of the metal plate 300, the thickness of the coating 310 can be controlled. After the coating 310 is formed, the coated plate 300 is allowed to cool to room temperature.

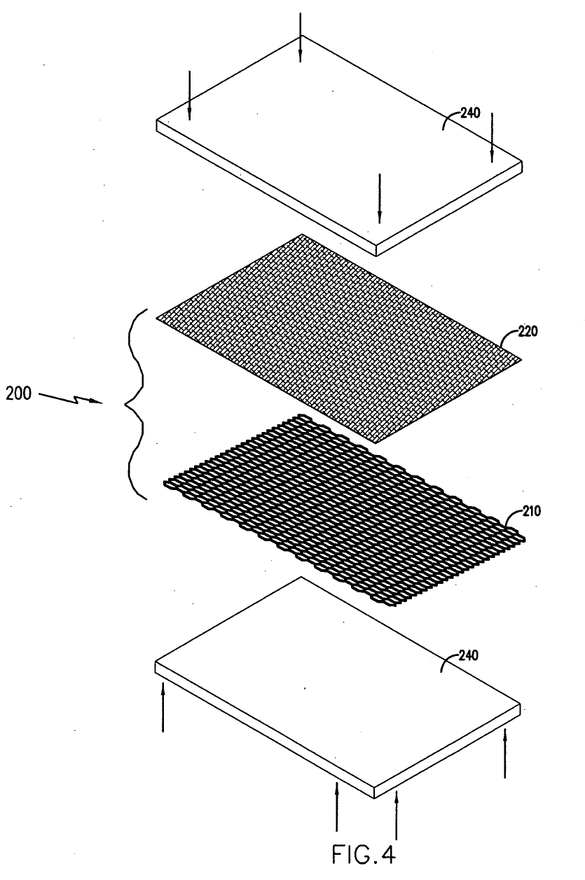

As shown in FIG. 4, the sub-assembly 200 can be formed by placing at least one layer of a wire structure 210 and a perforated thermoplastic sheet 220 on a first heated platen 230, with a second platen 240 overlying the wire structure 210. The first and second platens 230, 240 are then pressed together, thereby fusing the thermoplastic 220 to the wire structure 210. In one embodiment, the wire structure 210 is in the form of a layer of woven wire screen cloth. The first and second platens 230, 240 can then be opened and the fused screen 210/thermoplastic 220 that forms assembly 200 is removed and allowed to cool. Thermoplastic 220 may be fused to wire structure 210 by other methods as well, including applying heat by convection. First and second heated platens 230 and 240, respectively, may also include corrugated surfaces configured to form sub-assembly 200 into a corrugated shape.

In some embodiments and applications, the wire screen 210 that is fused with the perforated plastic sheet 220 can be shaped by a step where it is formed into a corrugated shape.

In accordance with one embodiment, a method for affixing the screen sub-assembly 200 to the metal plate 300 includes the step of positioning the thermoplastic coated metal plate 300 and the sub-assembly 200 above the top surface 154 of the rubber sheet 152 that is associated with the movable support structure 120. An operator then initiates the process by pressing a button or the like which causes a control signal (start signal) to be delivered to the programmable logic controller (PLC) 510 to start a cycle. The PLC 510 signals the microprocessor 500 and ultrasonic generator 530 to lower the piston 410 of the ultrasonic welding head 400. The piston 410 is driven downward toward the movable support structure 120 until the free distal end of the piston, ultrasonic horn 440, contacts the upper surface of the woven wire screen 210 and continues to exert a force until a prescribed pressure is reached. Subsequently, the ultrasonic frequency generator 530 excites the ultrasonic transducer 430 connected to the piston 410 which in turn excites the attached ultrasonic horn 440.

The microprocessor 500 then instructs (signals) the pneumatic piston 410 to move downward toward the movable support structure 120 until a distance is reached having been accurately monitored and digitally reported to the microprocessor 500 from a magnetic position indicating device which is configured to read the position of pneumatic piston 410 and be may incorporated into the feedback control of the piston 410, e.g., components 510, 520.

When the excited metal horn 440 contacts the wire sub-assembly 200, the thermoplastic sheet 220 is softened and pressed into the thermoplastic coated metal plate 300. When the prescribed distance is reached, the ultrasonic exciting signal is discontinued for a prescribed period of time to allow the molten plastic to cool and fuse with the plastic 310 of the metal plate 300.

In an embodiment of the present invention, distance of the piston 410 may or may not be measured and the piston 410 is driven downward toward the movable support structure 120 until the free, distal end of the piston 410, e.g., metal horn 440, contacts the upper surface of the woven wire screen 210 and exerts a force of approximately 20 to approximately 60 PSI (preferably approximately 30 PSI). Metal horn 440 is then excited with approximately 5 Watts to approximately 50 Watts (preferably approximately 15 Watts) for approximately 50 milliseconds to approximately 500 milliseconds, (preferably approximately 141 milliseconds). Wattage and duration of applied wattage is determined for each specific application and may be adjusted depending on the thickness of the wire-subassembly and coated substrate. In an embodiment wattage and duration of applied wattage are adjustable such that a total of approximately 50 Watt-seconds to approximately 300 Watt-seconds (preferably approximately 140 Watt-seconds) at approximately 30 PSI are applied. In an embodiment the prescribed period of time to allow the molten plastic to cool and fuse with the plastic 310 of the metal plate 300 is approximately 2000 milliseconds to approximately 4000 milliseconds (preferably approximately 3500 milliseconds).

After the ultrasonic exciting signal has been discontinued, the microprocessor 500 signals the ultrasonic head 400 and piston 410 to retract. The PLC 510 signals the stepper motor indexing drive controller 520 to cause the stepper motor 140 to turn and cause the movable support structure 120 to advance to the next position as programmed in the PLC 510. The stepper-motor index drive controller 520 signals the PLC 510 that the new position has been reached and the microprocessor 500 is signaled to repeat the ultrasonic welding cycle.

In an embodiment of the present invention multiple ultrasonic heads 400 are used. The ultrasonic heads 400 may be positioned along the cross beam of the bridge 160. In one configuration the outer most ultrasonic heads 400 (the heads closer to the edges of the woven wire sub-assembly 200) are configured such that ultrasonic horns 440 apply less Watt-seconds to the woven wire sub-assembly and the coated metal plate 300. Many different variations in positions of ultrasonic heads 400 and corresponding applied Watt-seconds may be applied to account for variations in thicknesses of the woven wire sub-assembly and the coated metal plate 300.

The weld/advance cycles are repeated until the programmed number of cycles are reached. For example, this may entail incrementally advancing the movable support structure 120 until welds are formed, at least at different intervals, along the entire length of the layered screen sub-assembly and plate that is supported by the movable support structure 120. The PLC 510 then signals the stepper motor index drive controller 520 to move the movable support structure 120 to its original starting position. This likely results in the movable support structure 120 moving toward the left in FIG. 1 until a substantial majority of the movable support structure 120 is to the left of the bridge 160.

The finished welded screen and metal plate are removed from the movable support structure 120.

FIG. 2 shows the woven wire sub-assembly 200 and thermoplastic coated metal plate 300 according to an embodiment of the present invention and prior to affixation to one another. The sub-assembly 200 and plate 300 shown in FIG. 2 can be used in the system 100 and method described above.

The present invention provides significant advantages over existing affixation systems, including reduced usage of electricity, shorter cooling times, elimination of chemical reactions, better affixation bonds, etc.

While the embodiments shown and described above are fully capable of achieving the objects and advantages of the present invention, it is to be understood that these embodiments are shown and described solely for the purposes of illustration and not for limitation.

What is claimed is:

1. A method of affixing a screen sub-assembly to a substrate, comprising the steps of:
depositing a thermoplastic material on a surface of the substrate;
placing the screen sub-assembly on top of the substrate, the screen sub-assembly including a screen element and a thermoplastic material;
placing the screen sub-assembly and the substrate on a movable surface;
driving the movable surface across a base support surface so as to position the screen sub-assembly and the substrate below an ultrasonic welding device; and
actuating the ultrasonic welding device to emit ultrasonic energy such that the screen sub-assembly is affixed to the substrate.

2. The method of claim 1, wherein the substrate includes a perforated metal plate, a cast metal frame or a welded frame, the perforated metal plate, the cast metal frame or the welded frame including a coating of thermoplastic powder.

3. The method of claim 2, further including the step of:
heating the metal plate to a temperature that causes the thermoplastic powder to melt on contact with the metal plate; and
adjusting the temperature of the metal plate so as to control a thickness of the thermoplastic coating.

4. The method of claim 1, wherein the screen sub-assembly includes a woven wire screen cloth and the thermoplastic material comprises a perforated thermoplastic sheet and is manufactured by placing the woven wire screen cloth and the thermoplastic material on a first platen; positioning a second platen over the woven wire screen cloth and the thermoplastic material; and pressing the first and second platens to fuse the thermoplastic sheet to the wire screen cloth.

5. The method of claim 1, wherein the movable surface includes a movable table that rides along an upper surface of a table and the step of driving the movable table comprises:
actuating a stepper motor that is operably connected to the movable table to cause the movable table to advance to a predetermined location.

6. The method of claim 1, wherein the ultrasonic welding device comprises:
a pneumatic piston;
an ultrasonic transducer disposed at a free end of the piston; and
an ultrasonic horn to direct ultrasonic energy generated by the transducer.

7. The method of claim 6, wherein the step of actuating the ultrasonic welding device comprises the steps of:
driving the pneumatic piston so that the ultrasonic horn contacts the screen sub-assembly;
exciting the ultrasonic horn with ultrasonic energy so as to cause the thermoplastic material of the screen sub-assembly to soften and be pressed into the thermoplastic material on the substrate.

8. The method of claim 7, wherein the step of actuating the ultrasonic welding device further comprises the step of moving the pneumatic piston a prescribed distance.

9. The method of claim 7, wherein the ultrasonic horn asserts a pressure of approximately 20 PSI to approximately 60 PSI against the screen sub-assembly.

10. The method of claim 9, wherein the ultrasonic horn is held in a fixed position and excited at approximately 10 Watts to approximately 20 Watts for approximately 100 milliseconds to approximately 500 milliseconds.

11. The method of claim 8, wherein the ultrasonic welding device includes a magnetic position device configured to determine the prescribed distance.

12. The method of claim 6, wherein the ultrasonic welding device includes multiple ultrasonic horns.

13. The method of claim 7, wherein the step of driving the pneumatic piston further includes the step of: exerting a force against the screen sub-assembly until a prescribed, inputted pressure is reached.

14. The method of claim 7, wherein the substrate comprises a perforated metal plate and a coating of thermoplastic powder and the method further includes the step of:
discontinuing for a period of time the actuation of the ultrasonic transducer when the pneumatic piston is driven a prescribed distance, thereby permitting molten thermoplastic of the sub-assembly to cool and fuse with the thermoplastic associated with the metal plate.

15. The method of claim 1, further including the steps of:
discontinuing for a period of time the actuation of the ultrasonic welding device after the screen sub-assembly has been affixed to the substrate in one location; and
repeating the steps of driving the movable surface so as to position another region of the screen sub-assembly and the substrate below an ultrasonic welding device; and actuating the ultrasonic welding device to emit ultrasonic energy that results in the screen sub-assembly being affixed to the substrate in this other region.

16. The method of claim 1, further including the step of:
placing bearings between a bottom surface of the movable support surface and an upper surface of the base support surface so as to facilitate movement of the movable support surface.

17. The method of claim 1, further including the step of:
entering a predetermined number of ultrasonic welding cycles that cause the movable support surface to move incrementally across the base support surface so as to position different regions of the screen sub-assembly/substrate combination underneath the ultrasonic welding device to permit the different regions to be sequentially affixed to one another; wherein for each welding cycle, a different location of the screen sub-assembly/substrate combination is subjected to the ultrasonic energy.

18. The method of claim 17, further including the step of:
returning the movable support surface to an original starting position where the screen sub-assembly/substrate combination is upstream of the ultrasonic welding device.

19. The product of the process of claim 1.

20. A system for affixing a screen sub-assembly to a substrate, comprising:
a support member that is movable relative to a reference surface, the support member being operatively connected to a controller that controllably and precisely moves the support member across the reference surface to a target position;
a bridge structure that is coupled to the support member and permits the movable support member to be driven thereunderneath;
a device configured to ultrasonically affix the screen sub-assembly to the substrate, the device being coupled to the bridge structure and including a movable piston that is vertically oriented and can be driven toward the movable support member when the movable support member is positioned underneath the piston, the device further including an ultrasonic transducer configured to generate ultrasonic energy at a distal tip of the piston, the target position being where the movable support member is located underneath the ultrasonic transducer; and
a processor operatively connected to the device for controlling movement of the piston and to the controller for driving the movable support member in an indexed manner so that it assumes the target position;
wherein the screen sub-assembly includes a screen element and a thermoplastic material and the substrate includes a perforated metal plate and a coating of thermoplastic powder.

21. The system of claim 20, further including a rubber covering disposed over an upper surface of the movable support member and bearings disposed between a bottom surface of the movable support member and an upper surface of the reference surface so as to facilitate movement of the movable support member.

22. The system of claim 20, wherein the piston includes a pneumatic piston having feedback control.

23. The system of claim 20, further including a metal horn attached to the ultrasonic transducer for directing the ultrasonic energy.

24. The system of claim 20, further including:
a driver configured to controllably and precisely drive the movable support member; and
a magnetic position indicating device configured to precisely measure a position of the ultrasonic transducer relative to the screen sub-assembly.

25. The system of claim 24, wherein the driver includes a stepper motor and a stepper motor indexing drive controller for controlling the stepper motor to cause incremental advancements of the movable support member across the reference surface.

26. The system of claim 25, further including a programmable logic controller (PLC) that is in communication with the controller and the stepper motor indexing drive controller, the PLC generating control signals to move the piston to a desired position and to exert a force against the screen sub-assembly until a prescribed pressure is achieved.

27. A screen assembly, comprising:
a screen sub-assembly including a screen element and a thermoplastic material; and
a substrate including a plate and a coating of thermoplastic,
wherein the thermoplastic material of screen-subassembly is affixed to the coating of thermoplastic by ultrasonic welds so as to secure the screen sub-assembly to the substrate.

28. The screen assembly of claim 27, wherein the screen sub-assembly includes a corrugated surface.

29. The screen assembly of claim 27, wherein the screen sub-assembly includes a flat surface.
